(19) United States
(12) Patent Application Publication
(10) Pub. No.: US 2014/0041907 A1
(43) Pub. Date: Feb. 13, 2014

(54) CORE SUBSTRATE AND PRINTED CIRCUIT BOARD USING THE SAME

(71) Applicant: SAMSUNG ELECTRO-MECHANICS CO., LTD., SUWON (KR)

(72) Inventors: Young Ji Kim, Suwon (KR); Kyoung Ro Yoon, Suwon (KR); Joung Gul Ryu, Suwon (KR)

(73) Assignee: SAMSUNG ELECTRO-MECHANICS CO., LTD., SUWON (KR)

(21) Appl. No.: 13/963,863

(22) Filed: Aug. 9, 2013

(30) Foreign Application Priority Data
Aug. 13, 2012 (KR) 10-2012-0088424

(51) Int. Cl. H05K 1/02

(52) U.S. Cl. CPC H05K 1/0204
USPC 174/252

(57) ABSTRACT

Disclosed herein is a core substrate including at least one connection member formed therein; heat radiation members positioned to be adjacent to the connection member and divided in plural; and insulation members formed between the heat radiation members divided in plural and between the connection member and the heat radiation member.

### CROSS REFERENCE TO RELATED APPLICATION

This application claims the benefit of Korean Patent Application No. 10-2012-0088424, filed on Aug. 13, 2012, entitled “Core Substrate and Printed Circuit Board Using the Same”, which is hereby incorporated by reference in its entirety into this application.

### BACKGROUND OF THE INVENTION

1. Technical Field

The present invention relates to a core substrate and a printed circuit board using the same.

2. Description of the Related Art

In accordance with the miniaturization, densification, and thinness of electronic components, research into a thin and multifunctional semiconductor package substrate has also been actively conducted.

Particularly, in order to implement a technology of stacking and mounting multiple semiconductor chips on a single substrate, that is, multi chip package (MCP) or a technology of stacking multiple substrates including chips mounted thereon, that is, package on package (POP), the development of a substrate having thermal expansion behavior similar to that of the chip and having an excellent warpage property after mounting the chips has been required.

In addition, due to an increase in an operation speed according to high performance of chips, a heat generation problem has been serious, and a counter measure against a warpage problem of the substrate has been also urgently required accordingly.

Therefore, in order to effectively discharge heat generated due to the driving of the chip to the outside after mounting the chip on the substrate, a substrate into which a metal core having excellent thermal conductivity is inserted has been manufactured.

The substrate in which the above-mentioned metal core are inserted is used to effectively discharge the heat generated due to the driving of the chip to the outside, such that generation of the substrate warpage due to the heat generated from the chip may be reduced. However, the substrate warpage may be generated due to a difference in heat strain between the metal core positioned at an inner side and a buildup layer formed to be stacked with respect to heat or pressure applied during a process of manufacturing the substrate into which the metal core is inserted.

Meanwhile, a structure of a substrate into which a metal core according to the prior art is inserted has been disclosed in U.S. Pat. No. 6,828,224.

### SUMMARY OF THE INVENTION

The present invention has been made in an effort to provide a core substrate capable of reducing warpage generated during a manufacturing process, and a printed circuit board using the same.

Further, the present invention has been made in an effort to provide a core substrate capable of controlling a degree of warpage in each part of a printed circuit board, and the printed circuit board using the same.

According to a preferred embodiment of the present invention, there is provided a core substrate including: at least one connection member; heat radiation members positioned to be adjacent to the connection member and divided in plural; and insulation members formed between the heat radiation members divided in plural and between the connection member and the heat radiation member.

The connection member may be made of at least one selected from a group consisting of copper (Cu), nickel (Ni), tungsten (W), molybdenum (Mo), tantalum (Ta), aluminum (Al), and an alloy thereof.

The heat radiation member may be made of at least one selected from a group consisting of copper (Cu), nickel (Ni), tungsten (W), molybdenum (Mo), tantalum (Ta), aluminum (Al), and an alloy thereof.

The core substrate may have a thickness of 30 μm or less.

The insulation member may be formed in a lattice pattern, and the heat radiation member may be formed so as to contact the insulation member in the lattice pattern.

The heat radiation member may be formed in a lattice pattern, and the insulation member may be formed so as to contact the heat radiation member in the lattice pattern.

Each of the plurality of heat radiation members may have a cylindrical shape.

According to another preferred embodiment of the present invention, there is provided a to printed circuit board including: a core substrate including at least one connection member, heat radiation members positioned to be adjacent to the connection member and divided in plural, and insulation members formed between the heat radiation members divided in plural and between the connection member and the heat radiation member; an insulation layer formed on the core substrate; a circuit pattern formed on the insulation layer; and a first via formed in the insulation layer and electrically connecting the connection member and the circuit pattern to each other.

The connection member may be made of at least one selected from a group consisting of copper (Cu), nickel (Ni), tungsten (W), molybdenum (Mo), tantalum (Ta), aluminum (Al), and an alloy thereof.

The heat radiation member may be made of at least one selected from a group consisting of copper (Cu), nickel (Ni), tungsten (W), molybdenum (Mo), tantalum (Ta), aluminum (Al), and an alloy thereof.

The core substrate may have a thickness of 30 μm or less.

The printed circuit board may further include a solder resist layer formed on the insulating layer and having an opening part exposing a portion of the circuit pattern.

The printed circuit board may further include a surface treatment layer formed on the circuit pattern exposed by the opening part.

The printed circuit board may further include an electronic component embedded in the core substrate in a thickness direction and having an electrode formed on one surface thereof; and a second via electrically connecting the circuit pattern and the electrode to each other.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a cross-sectional view showing a structure of a core substrate according to a preferred embodiment of the present invention;

FIG. 2 is a plan view showing pattern shapes of a heat radiation member and an insulation member of the core substrate according to the preferred embodiment of the present invention;

FIG. 3 is a cross-sectional view showing a structure of a printed circuit board according to the preferred embodiment of the present invention; and

FIG. 4 is a cross-sectional view showing a structure in which electronic components are embedded in the printed circuit board of FIG. 3.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

Core Substrate

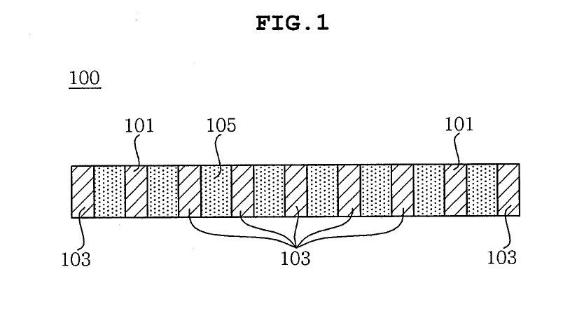

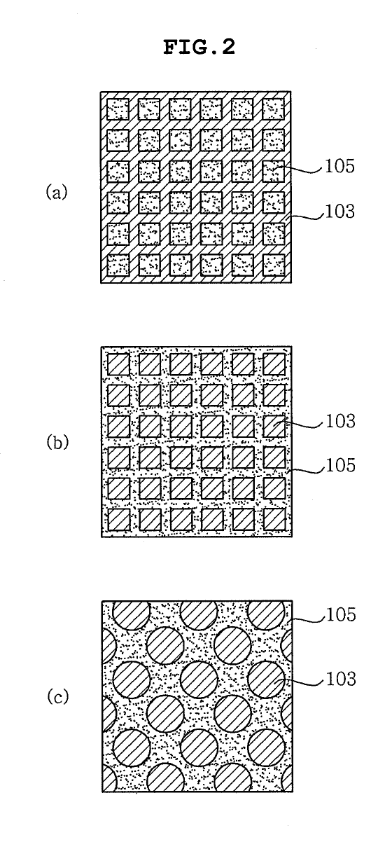

FIG. 1 is a cross-sectional view showing a structure of a core substrate according to a preferred embodiment of the present invention; and FIG. 2 is a plan view showing shapes of a heat radiation member and an insulation member in the core substrate of FIG. 1.

Referring to FIG. 1, the core substrate 100 according to the preferred embodiment of the present invention may be configured to include a connection member 101, heat radiation members 103 formed to be adjacent to the connection member 101 and to be divided in plural, and insulation members 105 formed between the heat radiation members 103 divided in plural and between the connection member 101 and the heat radiation member 103.

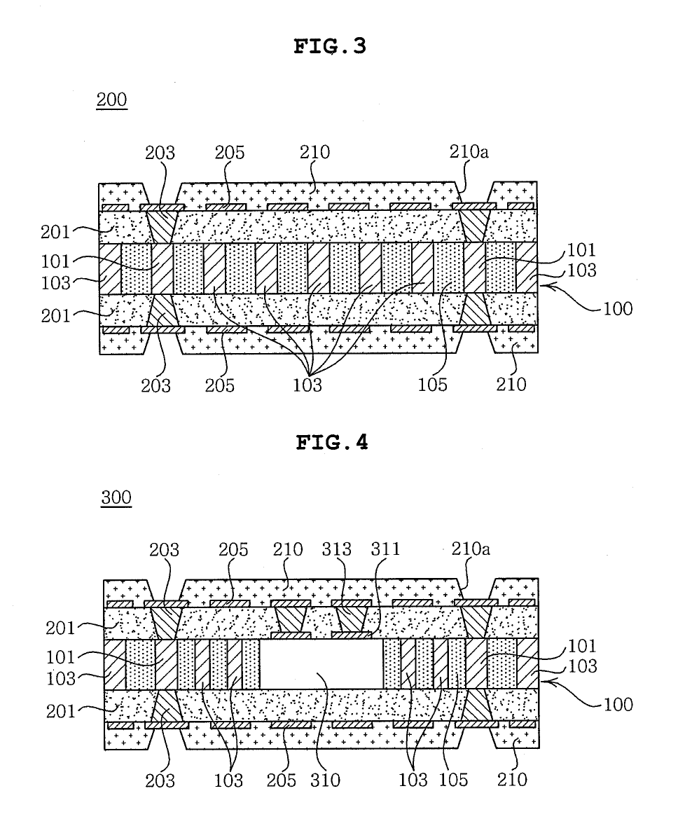

According to the present embodiment, the connection member 101 is electrically connected to a via 203 formed in an insulation layer 201 formed on the core substrate 100 through a post process to serve as a bridge for interlayer connection of circuit patterns 205, as shown in FIG. 3.

According to the present embodiment, the connecting member 101 may be made of at least one selected from a group consisting of copper (Cu), nickel (Ni), tungsten (W), molybdenum (Mo), tantalum (Ta), aluminum (Al), and alloy thereof, but is not limited thereto.

According to the present embodiment, the heat radiation members 103 may be formed to be adjacent to the connecting member 101 and divided in plural, as shown in FIG. 1.

Here, the heat radiation member 103 may be made of at least one selected from a group consisting of copper (Cu), nickel (Ni), tungsten (W), molybdenum (Mo), tantalum (Ta), aluminum (Al), and alloy thereof, similar to the above-mentioned connection member 101, but is not limited thereto.

A heat radiation member of the core substrate according to the prior art is not formed to be divided as in the present invention. Therefore, when the printed circuit board is manufactured using the core substrate according to the prior art, warpage may be generated in the printed circuit board by residual stress of the heat radiation member corresponding to heat or pressure applied to the product.

That is, the heat or the pressure may be applied to the product at the time of manufacturing the printed circuit board. In this case, the core substrate made of a metal and a buildup layer made of an insulation material and a metal have different heat strains, such that the warpage may be generated in the printed circuit board to be manufactured.

Therefore, the heat radiation member 103 made of a metal having a relatively large heat strain is divided in plural, and insulation members 105 having a relatively small heat strain are formed therebetween, such that the residue stress that has been concentrated on one portion in the prior art may be dispersed over the entire core substrate 100.

As described above, as the residual stress concentrated on one portion of the core substrate 100 is dispersed, the degree of warpage of the printed circuit board formed by a post process may be controlled.

In this case, the number of divided heat radiation members 103 may be controlled in some cases.

For example, when there are a region at which a degree of warpage should be minimized and a region at which a degree of warpage should be maximized in order to form the printed circuit board 200 to be entirely plane, the number of divided heat radiation members 103 positioned at the corresponding region may be appropriately controlled, thereby making it possible to minimize or maximize the degree of warpage in each region.

In addition, the number of divided heat radiation members 103 may be simply controlled in each region as described above or areas of the heat radiation member 103 and the insulation member 105 may be controlled in each region.

Further, the core substrate 100 according to the present embodiment may include the insulation member 105 formed between each of the heat radiation members 103 divided in plural and between the heat radiation member 103 and the connection member 101.

The respective heat radiation members 103 divided in plural, and the heat radiation member 103 and the connection member 101 may be electrically insulated from each other by the insulation member 105.

This insulation member 105 may be formed by etching a portion of a metal core to form a through-hole (not shown) and then filling an insulation material in the through-hole (not shown), which is only an example, but the method of forming the insulation member 105 is not particularly limited thereto.

In this case, the heat radiation member 103 may be formed in a lattice pattern, and the insulation member 105 may be formed so as to contact the heat radiation member 103 in the lattice pattern, as shown in FIG. 2A.

Alternately, on the contrary, the insulation member 105 may be formed in the lattice pattern, and the heat radiation member 103 may be formed so as to contact the insulation member 105 in the lattice pattern, as shown in FIG. 2B.

Alternately, each of the plurality of heat radiation members 103 may be formed in a cylindrical shape to be spaced apart from the insulation member 105, as shown in FIG. 2C.

Shapes of the heat radiation member 103 and the insulation member 105 of the core substrate 100 according to the present embodiment are not limited to the above mentioned examples, but may be variously implemented.

Here, as a material of the insulation member 105, a resin insulation material may be used. As the resin insulation material, a thermo-setting resin such as an epoxy resin, a thermo-plastic resin such as polyimide, a resin having a reinforcement material such as a glass fiber or an inorganic filler impregnated in them, for example, a prepreg may be used. In addition, a thermo-setting resin, a photo-setting resin, and/or the like, may be used, but the resin insulation material is not particularly limited thereto.

According to the present embodiment, the core substrate 100 may have a thickness of 30 μm or less, but is not particularly limited thereto.

The reason is that in accordance with recent trend toward the thinness of the printed circuit board, the thickness of the core substrate inserted therein should also become thin. That is, in the case in which the thickness of the core substrate is the same as that in the prior art and only the buildup layer formed on the core substrate is thin, since the heat strain of the core substrate is larger than that of the buildup layer, the warpage may be generated in the printed circuit board.

Printed Circuit Board

FIG. 3 is a cross-sectional view showing a structure of a printed circuit board according to the preferred embodiment of the present invention.

Referring to FIG. 3, the printed circuit board 200 according to the preferred embodiment of the present invention may be configured to include a core substrate 100 including a connection member 101, heat radiation members 103 positioned to be adjacent to the connection member 101 and divided in plural, and insulation members 105 formed between the heat radiation members 103 divided in plural and between the connection member 101 and the heat radiation member 103, an insulation layer 201 formed on the core substrate 100, a circuit pattern 205 formed on the insulation layer 201, and a first via 203 formed in the insulation layer 201 and electrically connecting the connection member 101 and the circuit pattern 205.

In addition, although not shown, a surface treatment layer (not shown) may be formed on the core substrate 100 in order to improve reliability of adhesion with the insulation layer 201. In this case, the surface treatment layer (not shown) may be an oxide layer, a copper sputter, or a copper plating layer, but is not particularly limited thereto.

According to the present embodiment, the core substrate 100 is inserted into the printed circuit board 200 for mounting a semiconductor chip thereon, and then at the time of operation of the semiconductor chip, the heat generated from the semiconductor chip is discharged to the outside, thereby making it possible to prevent the warpage of the printed circuit board 200.

In the present embodiment, the core substrate 100 may be configured of at least one of the connection member 101, the heat radiation members 103 positioned to be adjacent to the connection member 101 and divided in plural, and the insulation members 105 formed between the heat radiation members 103 divided in plural and between the connection member 101 and the heat radiation member 103.

Here, the connection member 101 may be electrically connected to the first via 203 formed in the insulation layer 201 to serve as the bridge for interlayer connection of the circuit patterns 205.

Further, the connecting member 101 may be made of at least one selected from a group consisting of copper (Cu), nickel (Ni), tungsten (W), molybdenum (Mo), tantalum (Ta), aluminum (Al), and an alloy thereof, but is not particularly limited thereto.

In addition, the heat radiation member 103 performs a function of effectively discharging the heat generated from the semiconductor chip (not shown) at the time of driving the semiconductor chip (not shown) that will be subsequently mounted on the printed circuit board 200.

According to the present embodiment, the heat radiation member 103 may be made of at least one selected from a group consisting of copper (Cu), nickel (Ni), tungsten (W), molybdenum (Mo), tantalum (Ta), aluminum (Al), and alloy thereof, similar to the connection member 101, but is not particularly limited thereto.

According to the present embodiment, the heat radiation members 103 may be formed to be adjacent to the connecting member 101 and divided in plural, as shown in FIG. 3.

A heat radiation member of the core substrate according to the prior art is not formed to be divided as in the present invention. Therefore, when the printed circuit board is manufactured using the core substrate according to the prior art, warpage may be generated in the printed circuit board by residual stress of the heat radiation member corresponding to heat or pressure applied to the product.

That is, the heat or the pressure may be applied to the product at the time of manufacturing the printed circuit board, and in this case, the core substrate made of a metal and a buildup layer made of an insulation material and a metal have different heat strains from each other, such that the warpage may be generated in the printed circuit board to be manufactured.

Therefore, the heat radiation member 103 made of a metal having a relatively large heat strain is divided in plural, and insulation members 105 having a relatively small heat strain are formed therebetween as in the present embodiment, such that the residue stress that has been concentrated on one portion in the prior art may be dispersed over the entire core substrate 100.

As described above, as the residual stress concentrated on one portion of the core substrate 100 is dispersed, the degree of warpage of the printed circuit board formed by a post process may be controlled.

In this case, the number of divided heat radiation members 103 may be controlled in some cases.

For example, when there are a region at which a degree of warpage should be minimized and a region at which a degree of warpage should be maximized in order to form the printed circuit board 200 to be entirely plane, the number of divided heat radiation members 103 positioned at the corresponding region may be appropriately controlled, thereby making it possible to minimize or maximize the degree of warpage in each region.

In addition, the number of divided heat radiation members 103 may be simply controlled in each region as described above, and areas of the heat radiation member 103 and the insulation member 105 may be controlled in each region.

According to the present embodiment, the insulation member 105 are formed between the heat radiation member 103 and the connection member 101 as well as between the respective heat radiation members 103 to electrically insulate between the heat radiation member 103 and the connection member 101.

This insulation member 105 may be formed by etching a portion of a metal core to form a through-hole (not shown) and then filling an insulation material in the through-hole (not shown), which is only an example, but the method of forming the insulation member 105 is not particularly limited thereto.

In this case, the heat radiation member 103 may be formed in the lattice pattern, and the insulation member 105 may be formed so as to contact the heat radiation member 103 in the lattice pattern, as shown in FIG. 2A.

Alternately, on the contrary, the insulation member 105 may be formed in the lattice pattern, and the heat radiation member 103 may be formed so as to contact the insulation member 105 in the lattice pattern, as shown in FIG. 2B.

Alternately, each of the plurality of heat radiation members 103 may be formed in a cylindrical shape so as to be spaced apart from the insulation member 105, as shown in FIG. 2C.

Shapes of the heat radiation member 103 and the insulation member 105 of the core substrate 100 according to the present embodiment are not limited to the above mentioned examples, but may be variously implemented.

Here, as a material of the insulation member 105, a resin insulation material may be used. As the resin insulation material, a thermo-setting resin such as an epoxy resin, a thermo-plastic resin such as polyimide, a resin having a reinforcement material such as a glass fiber or an inorganic filler impregnated in them, for example, a prepreg may be used. In addition, a thermo-setting resin, a photo-setting resin, and/or the like, may be used, but the resin insulation material is not particularly limited thereto.

According to the present embodiment, the core substrate 100 may have a thickness of 30 μm or less, but is not particularly limited thereto.

The reason is that in accordance with recent trend toward the thinness of the printed circuit board, the thickness of the core substrate inserted therein should also become thin. That is, In the case in which the thickness of the core substrate is the same as that in the prior art and only the buildup layer formed on the core substrate is thin, since the heat strain of the core substrate is larger than that of the buildup layer, the warpage may be generated in the printed circuit board.

The printed circuit board 200 according to the preferred embodiment of the present invention may further include the insulation layer 201 formed on the core substrate 100, the first via 203 formed on the insulation layer 201, and the circuit pattern 205.

Although the case in which buildup layers including the insulation layer 201, the first via 203, and the circuit pattern 205 are formed on the both surfaces of the core substrate 100, respectively, is shown in FIG. 3, the present invention is not particularly limited thereto, but the buildup layer may be formed on only one surface of the core substrate 100.

In addition, although the case in which a single buildup layer is formed on both sides of the core substrate 100 is shown in the present embodiment, at least two buildup layers may also be formed.

Here, the insulation layer 201 may be made of resin insulation materials, similar to the above-mentioned insulation member 105, but is not particularly limited thereto.

According to the present embodiment, a process for forming the first via 203 and the circuit pattern 205 on the insulation layer 201 is as follows. A via hole (not shown) is formed at a position corresponding to the connection member 101 of the core substrate 100 in the insulation layer 201, a seed layer (not shown) is formed on the insulation layer 201 as well as an inner wall of the via hole (not shown), and a plating resist pattern (not shown) having an opening part for forming the circuit pattern 205 is then formed on the seed layer (not shown).

Then, a plating process is performed to form a plating layer on the opening part for forming the circuit pattern 205, the plating resist pattern (not shown) is removed, and the exposed seed layer (not shown) is then removed, thereby making it possible to form the first via 203 and the circuit pattern 205.

Here, each of the seed layer and the plating layer may be formed by an electroless plating method and an electro plating method. Meanwhile, a process of forming the via hole and the plating resist pattern is a technology that has been widely known in the art. Therefore, a detailed description thereof will be omitted.

In addition, the printed circuit board 200 according to the present embodiment may further include a solder resist layer 210 formed on the insulation layer 201 and having an opening part 210a exposing a portion of the circuit pattern 205, for example, a portion that will become a pad.

The solder resist layer 210 serves as a protection layer protecting the outermost circuit and is formed for electrical insulation. The solder resist layer 210 may be made of, for example, solder resist ink, a solder resist film, an encapsulant, or the like, as known in the art, but is not particularly limited thereto.

In addition, the printed circuit board 200 according to the preferred embodiment of the present invention may further include a surface treatment layer (not shown) formed on the circuit pattern 205 exposed by the opening part 210a of the solder resist layer 210.

The surface treatment layer (not shown), which is formed in order to prevent the circuit pattern 205 to be oxidized and increase adhesion strength with a semiconductor chip bump that will be subsequently connected thereto, is not particularly limited, but may be formed by any method known in the art. For example, the surface treatment layer may be formed by electro gold plating, immersion gold plating, organic solderability preservative (OSP) or immersion tin plating, immersion silver plating, electroless nickel and immersion gold (ENIG), direct immersion gold (DIG) plating, hot air solder leveling (HASL), or the like.

Meanwhile, FIG. 4 shows a structure of a printed circuit board embedded with electronic components.

Here, since the printed circuit board has the same structure as that of the printed circuit board shown in FIG. 3, a description of the same components as those of the printed circuit board of FIG. 3 will be omitted.

Referring to FIG. 4, the printed circuit board 300 may further include an electronic component 310 embedded in the core substrate 100 of the printed circuit board 200 shown in FIG. 3 in a thickness direction.

In this case, one surface of the electronic component 310 may be provided with an electrode 311 connected to the circuit pattern 205, and the insulation layer 201 may be formed with a second via 313 electrically connecting the circuit pattern 205 and the electrode 311 of the electronic component 310 to each other.

Further, heat radiation member 103 between the electronic component 310 embedded in the core substrate 100 and the connecting member 101 may be divided into at least two as shown in FIG. 4, but is not particularly limited thereto.

As set forth above, according to the preferred embodiments of the present invention, the heat radiation member performing a heat radiation function is formed to be divided in plural in the core substrate inserted into the printed circuit board to disperse the residual stress of the heat radiation member corresponding to the heat and pressure applied from the outside, thereby making it possible to reduce the generation of the warpage of the printed circuit board.

In addition, according to the preferred embodiment of the present invention, the number of divided heat radiation members is applied to be different in each region with respect to the entire printed circuit board to control the degree of warpage in each region, thereby making it possible to cope with warpage in various forms generated during a manufacturing process of the printed circuit board.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A core substrate comprising:
at least one connection member;
heat radiation members positioned to be adjacent to the connection member and divided in plural; and
insulation members formed between the heat radiation members divided in plural and between the connection member and the heat radiation member.

2. The core substrate as set forth in claim 1, wherein the connection member is made of at least one selected from a group consisting of copper (Cu), nickel (Ni), tungsten (W), molybdenum (Mo), tantalum (Ta), aluminum (Al), and an alloy thereof.

3. The core substrate as set forth in claim 1, wherein the heat radiation member is made of at least one selected from a group consisting of copper (Cu), nickel (Ni), tungsten (W), molybdenum (Mo), tantalum (Ta), aluminum (Al), and an alloy thereof.

4. The core substrate as set forth in claim 1, wherein it has a thickness of 30 μm or less.

5. The core substrate as set forth in claim 1, wherein the insulation member is formed in a lattice pattern, and the heat radiation member is formed so as to contact the insulation member in the lattice pattern.

6. The core substrate as set forth in claim 1, wherein the heat radiation member is formed in a lattice pattern, and the insulation member is formed so as to contact the heat radiation member in the lattice pattern.

7. The core substrate as set forth in claim 1, wherein each of the plurality of heat radiation members has a cylindrical shape.

8. A printed circuit board comprising:
a core substrate including at least one connection member, heat radiation members positioned to be adjacent to the connection member and divided in plural, and insulation members formed between the heat radiation members divided in plural and between the connection member and the heat radiation member;
an insulation layer formed on the core substrate;
a circuit pattern formed on the insulation layer; and
a first via formed in the insulation layer and electrically connecting the connection member and the circuit pattern to each other.

9. The printed circuit board as set forth in claim 8, wherein the connection member is made of at least one selected from a group consisting of copper (Cu), nickel (Ni), tungsten (W), molybdenum (Mo), tantalum (Ta), aluminum (Al), and an alloy thereof.

10. The printed circuit board as set forth in claim 8, wherein the heat radiation member is made of at least one selected from a group consisting of copper (Cu), nickel (Ni), tungsten (W), molybdenum (Mo), tantalum (Ta), aluminum (Al), and an alloy thereof.

11. The printed circuit board as set forth in claim 8, wherein the core substrate has a thickness of 30 μm or less.

12. The printed circuit board as set forth in claim 8, further comprising a solder resist layer formed on the insulating layer and having an opening part exposing a portion of the circuit pattern.

13. The printed circuit board as set forth in claim 12, further comprising a surface treatment layer formed on the circuit pattern exposed by the opening part.

14. The printed circuit board as set forth in claim 8, further comprising:
an electronic component embedded in the core substrate in a thickness direction and having an electrode formed on one surface thereof; and
a second via electrically connecting the circuit pattern and the electrode to each other.
